(19) United States
(12) Patent Application Publication
(10) Pub. No.: US 2025/0393255 A1
(43) Pub. Date: Dec. 25, 2025

(54) OXIDE SEMICONDUCTOR, LAMINATED STRUCTURE, THIN FILM TRANSISTOR, AND ELECTRONIC DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP); Emi KAWASHIMA, Tokyo (JP); Yuki TSURUMA, Tokyo (JP); Daichi SASAKI, Tokyo (JP)

(73) Assignees: Japan Display Inc., Tokyo (JP); IDEMITSU KOSAN CO., LTD., Tokyo (JP)

(21) Appl. No.: 19/310,965

(22) Filed: Aug. 27, 2025

Related U.S. Application Data
(63) Continuation of application No. PCT/JP2024/009579, filed on Mar. 12, 2024.

(30) Foreign Application Priority Data
Mar. 17, 2023 (JP) 2023-043031

(51) Int. Cl. H10D 30/67; C30B 29/22; H10D 62/40; H10D 86/60

(52) U.S. Cl. CPC H10D 30/6755; C30B 29/22; H10D 30/6732; H10D 62/40; H10D 86/60

(57) ABSTRACT

An oxide semiconductor film includes a plurality of crystal grains over a substrate. The oxide semiconductor film includes indium and a first metal element selected from the group consisting of aluminum (Al), gallium (Ga), yttrium (Y), scandium (Sc), and lanthanoid elements. When a crystal orientation at each of a plurality of measurement points of the oxide semiconductor film is obtained based on an electron diffraction pattern obtained by transmitting an electron beam irradiated from a direction intersecting a thickness direction of the oxide semiconductor film, an average value of KAM values calculated at the plurality of measurement points is greater than or equal to 0.3 degrees.

### CROSS-REFERENCE TO RELATED APPLICATIONS

This application is a Continuation of International Patent Application No. PCT/JP2024/009579, filed on Mar. 12, 2024, which claims the benefit of priority to Japanese Patent Application No. 2023-043031, filed on Mar. 17, 2023, the entire contents of each are incorporated herein by reference.

### FIELD

An embodiment of the present invention relates to an oxide semiconductor film having a polycrystalline structure (Poly-OS). Further, an embodiment of the present invention relates to a laminated structure including a Poly-OS film. Furthermore, an embodiment of the present invention relates to a thin film transistor including a Poly-OS film. Moreover, an embodiment of the present invention relates to an electronic device including the thin film transistor.

### BACKGROUND

In recent years, instead of a silicon semiconductor film using amorphous silicon, low-temperature polysilicon, and single-crystal silicon, a thin film transistor in which an oxide semiconductor film is used for a channel has been developed (for example, see Japanese laid-open patent publication Nos. 2021-141338, 2014-099601, 2021-153196, 2018-006730, 2016-184771, and 2021-108405). The thin film transistor including an oxide semiconductor film can be manufactured with a simple structure and low-temperature process, similar to a thin film transistor including an amorphous silicon film. Further, the thin film transistor including an oxide semiconductor film is known to have a higher field-effect mobility than the thin film transistor including an amorphous silicon film.

### SUMMARY

An oxide semiconductor film according to an embodiment of the present invention includes a plurality of crystal grains over a substrate. The oxide semiconductor film includes indium and a first metal element selected from the group consisting of aluminum (Al), gallium (Ga), yttrium (Y), scandium (Sc), and lanthanoid elements. When a crystal orientation at each of a plurality of measurement points of the oxide semiconductor film is obtained based on an electron diffraction pattern obtained by transmitting an electron beam irradiated from a direction intersecting a thickness direction of the oxide semiconductor film, an average value of KAM values calculated at the plurality of measurement points is greater than or equal to 0.3 degrees.

A laminated structure according to an embodiment of the present invention includes the oxide semiconductor film and a silicon oxide film under and in contact with the oxide semiconductor film.

A thin film transistor according to an embodiment of the present invention includes the oxide semiconductor film as a channel.

An electronic device according to an embodiment of the present invention includes the thin film transistor.

### BRIEF DESCRIPTION OF DRAWINGS

FIG. 1 is a schematic diagram illustrating a TEM-ED mapping method.

FIG. 2 is a schematic cross-sectional view showing a configuration of a thin film transistor according to an embodiment of the present invention.

FIG. 3 is a schematic diagram showing an electronic device according to an embodiment of the present invention.

FIG. 4 is an inverse pole figure of an oxide semiconductor layer (Poly-OS film) of an example sample.

FIG. 5 is an IPF map of an oxide semiconductor layer (Poly-OS film) of an example sample.

FIG. 6 is a KAM map of an oxide semiconductor layer (Poly-OS film) of an example sample.

FIG. 7 is a graph showing a distribution of KAM values of oxide semiconductor layers (Poly-OS films) of example samples.

FIG. 8 is a graph showing a depth average KAM value in oxide semiconductor layers (Poly-OS films) of example samples.

### DESCRIPTION OF EMBODIMENTS

The field effect mobility of a thin film transistor including a conventional oxide semiconductor film is not so high even when a crystalline oxide semiconductor film is used in the thin film transistor. Therefore, it has been desired to improve the crystal structure of the oxide semiconductor film used in the thin film transistor and thereby improve the field effect mobility of the thin film transistor.

In view of the above problems, an embodiment of the present invention can provide an oxide semiconductor film having a novel crystal structure. Further, an embodiment of the present invention can provide a laminated structure including the oxide semiconductor film having a novel crystal structure. Furthermore, an embodiment of the present invention can provide a thin film transistor including the oxide semiconductor film having a novel crystal structure. Moreover, an embodiment of the present invention can provide an electronic device including the thin film transistor.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a thin film transistor and a pixel electrode do not overlap in a plan view when expressed as “a pixel electrode over a thin film transistor.” On the other hand, the expression “a pixel electrode vertically over a thin film transistor” means a positional relationship in which the thin film transistor and the pixel electrode overlap in a plan view. In addition, a plan view refers to viewing from a direction perpendicular to a surface of the substrate.

In the present specification and the like, the terms “film” and “layer” can be optionally interchanged with one another.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification and the like, the expression “α includes A, B, or C,” “α includes any of A, B, or C,” or “α includes one selected from a group consisting of A, B and C,” and the like does not exclude the case where α includes a plurality of combinations of A to C unless otherwise specified. Further, these expressions do not exclude the case where α includes other components.

In addition, the following embodiments can be combined with each other as long as there is no technical contradiction.

### First Embodiment

### 1. Composition of Oxide Semiconductor Film

The oxide semiconductor film according to the present embodiment contains indium (In) and at least one or more metal elements (M) other than indium. It is preferable that the composition ratio of the oxide semiconductor film has an atomic ratio of indium and at least one or more metal elements which satisfies Formula (1). In other words, it is preferable that the ratio of indium to all metal elements in the oxide semiconductor film is greater than or equal to 50%. When the ratio of indium in the oxide semiconductor film increases, the oxide semiconductor film having crystallinity can be formed. Further, it is preferable that a crystal structure of the oxide semiconductor film has a bixbyite structure. When the ratio of indium in the oxide semiconductor film increases, the oxide semiconductor film having a bixbyite structure can be formed.

$$0.01 < \frac{[ M ]}{[ ln ] + [ M ]} < 0.5 \qquad ( 1 )$$

It is preferable that at least one metal element is, for example, one or more elements selected from the group consisting of aluminum (Al), gallium (Ga), yttrium (Y), scandium (Sc), and lanthanoid elements.

The first metal element included in the at least one metal element is preferably gallium. Since gallium belongs to the same Group 13 as indium, it does not inhibit the crystallinity of the oxide semiconductor film. That is, even when the oxide semiconductor film contains gallium as the first metal element, the oxide semiconductor film having a bixbyite structure can be formed.

When the first metal element is gallium, the oxide semiconductor film may contain a second metal element (M2) selected from the group consisting of aluminum, yttrium, scandium, and lanthanoid elements. In this case, it is preferable that the atomic ratio of indium, gallium, and the second metal element in the composition ratio of the oxide semiconductor film satisfies formulas (2), (3), and (4). Since the ratio of the second metal element is lower than the ratio of indium or gallium, the second metal element does not inhibit the crystallinity of the oxide semiconductor film.

$$0.7 \leq \frac{[ ln ]}{[ ln ] + [ Ga ] + [ M 2 ]} \leq 0.98 \qquad ( 2 )$$

$$0.01 \leq \frac{[ Ga ]}{[ ln ] + [ Ga ] + [ M 2 ]} < 0.2 \qquad ( 3 )$$

$$0.01 \leq \frac{[ M 2 ]}{[ ln ] + [ Ga ] + [ M 2 ]} < 0.1 \qquad ( 4 )$$

Although the details of a method for manufacturing the oxide semiconductor film are described later together with a method for manufacturing a thin film transistor, the oxide semiconductor film can be formed by a sputtering method. The composition of the oxide semiconductor film formed by the sputtering method depends on the composition of the sputtering target. When the sputtering target has the above-described composition, the oxide semiconductor film without composition deviation of the metal elements can be formed by the sputtering method. Therefore, the composition of the metal elements (e.g. indium and gallium etc.) in the oxide semiconductor film may be equivalent to the composition of the metal elements in the sputtering target. For example, the composition of the metal elements in the oxide semiconductor film can be specified based on the composition of the metal elements in the sputtering target. In addition, oxygen contained in the oxide semiconductor film is not limited thereto because it changes depending on the process conditions of the sputtering method.

Further, the composition of the metal elements in the oxide semiconductor film can be specified by X-ray fluorescence analysis, electron Since the oxide probe micro analyzer (EPMA) analysis, or the like. semiconductor film has a polycrystalline structure, the composition of the oxide semiconductor film may be specified by X-ray diffraction (XRD). Specifically, the composition of the metal elements in the oxide semiconductor film can be specified based on the crystal structure and lattice constant of the oxide semiconductor film obtained by XRD.

### 2. Crystal Structure of Oxide Semiconductor Film

The oxide semiconductor film has a polycrystalline structure including a plurality of crystal grains. Although the details of the configuration of the oxide semiconductor film are described later, the oxide semiconductor film having a novel polycrystalline structure different from a conventional oxide semiconductor film can be formed using a polycrystalline oxide semiconductor (Poly-OS) technique. Therefore, hereinafter, the oxide semiconductor film having a polycrystalline structure according to the present embodiment may be referred to as a Poly-OS film in order to distinguish it from the conventional oxide semiconductor film having a polycrystalline structure.

Each crystal grain in the Poly-OS film may be composed of a plurality of crystallites. Although the crystallite diameter is not particularly limited to a certain value, the crystallite diameter is preferably greater than or equal to 1 nm, more preferably greater than or equal to 10 nm, and further preferably greater than or equal to 15 nm. The crystallite diameter can be measured by an electron beam diffraction method, an XRD method, or the like.

Although the crystal structure of the Poly-OS film is not limited to a certain structure, it is preferable that the Poly-OS film has a bixbyite structure. The crystal structure of the Poly-OS film can be specified by an XRD method or an electron beam diffraction method.

In addition, a plurality of crystal grains may have one type of crystal structure, or may have a plurality of types of crystal structures in the Poly-OS film. When the Poly-OS film has the plurality of types of crystal structures, it is preferable that one of the plurality of types of crystal structures is a bixbyite structure.

The crystal structure of the Poly-OS film is different from that of the conventional oxide semiconductor film having a polycrystalline structure. Specifically, the present inventors found that the crystal grains included in the

Poly-OS film have characteristics different from those of the crystal grains included in the conventional oxide semiconductor film. Such characteristics of the Poly-OS film can be measured by a transmission electron microscopy electron diffraction mapping (TEM-ED mapping) method. In addition, the TEM-ED mapping method may be referred to as an automated crystal orientation mapping transmission electron microscopy (ACOM-TEM) method. Hereinafter, measurement of an oxide semiconductor film by the TEM-ED mapping method is described.

### 2-1. TEM-ED Mapping Method

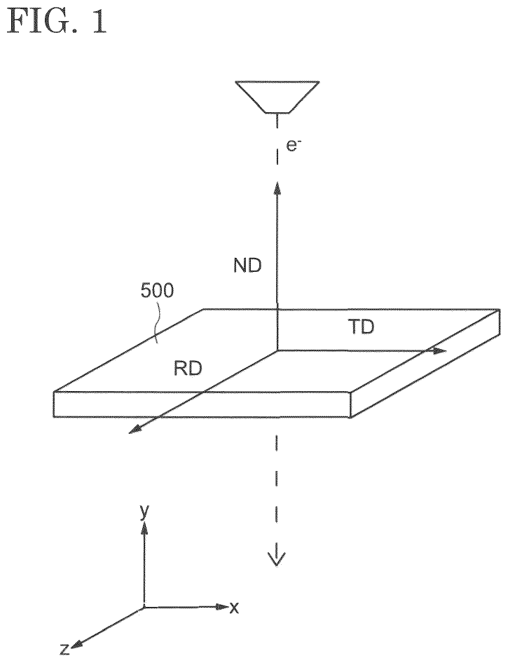

FIG. 1 is a schematic diagram illustrating the TEM-ED mapping method. The TEM-ED mapping method is an analysis method in which an electron beam is irradiated onto a measurement region of an object to be measured, an electron diffraction pattern observed after passing through the object to be measured is analyzed, and the crystal orientation in the measurement region of the object to be measured is measured. Since the electron diffraction pattern is continuously analyzed at a plurality of measurement points in the measurement region, information on the crystal orientation within or between crystal grains can be obtained. In the TEM-ED mapping method, a TEM sample 500 is used as the object to be measured. Therefore, the TEM-ED mapping method is capable of obtaining information on the crystal orientation in a smaller measurement region than the EBSD (Electron Back Scattered Diffraction) method using a SEM sample.

In addition, when the TEM-ED mapping method is applied to the oxide semiconductor layer 140 of the thin film transistor 10, a thin film sample including a cross section of the oxide semiconductor layer 140 of the thin film transistor 10 is used as the TEM sample 500. The TEM-ED mapping method is a measurement of a micro region using a TEM sample. Therefore, although the step interval of the measurement points at which the electron beam diffraction pattern is observed is, for example, greater than or equal to 1 nm, the step interval is not limited thereto. However, in the measurement of the crystal orientation, it is preferable to have a large number of measurement points in the thickness direction of the oxide semiconductor film. For example, the step interval is less than or equal to ⅕, preferably less than or equal to 1/10, and more preferably less than or equal to 1/30 of the thickness of the oxide semiconductor film.

In the TEM-ED mapping method, a coordinate system based on the TEM sample 500 (ND (Normal Direction), TD (Transverse Direction), and RD (Reference Direction)) is used, as shown in FIG. 1. In the coordinate system based on the TEM sample 500, the normal direction to the surface of the TEM sample 500 is the ND. The ND, TD, and RD are orthogonal to each other. The electron beam is irradiated to the TEM 500 from the ND.

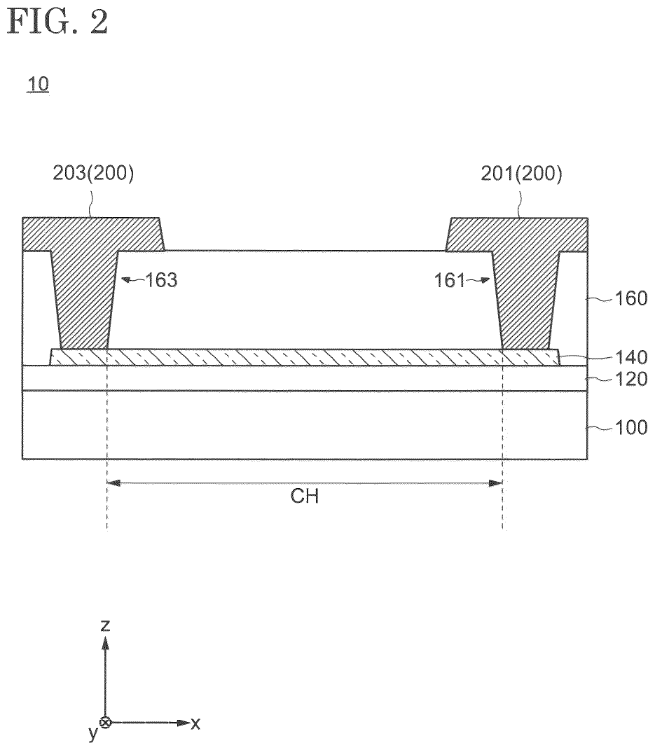

FIG. 1 shows a coordinate system (x-axis, y-axis, and z-axis) based on the thin film transistor 10 or the oxide semiconductor layer 140, which is described later (see FIG. 2), as well as the coordinate system based on the TEM sample 500. In the coordinate system based on the thin film transistor 10, the thickness direction of the oxide semiconductor layer 140 is the z-axis. The x-axis, y-axis, and z-axis are orthogonal to each other. Therefore, the x-axis and y-axis are in-plane directions of the oxide semiconductor layer 140.

Therefore, in the present specification, the ND, the TD, and the RD in the TEM-ED mapping method are described as corresponding to the y-axis, x-axis, and z-axis of the thin film transistor 10, respectively.

### 2-2. Inverse Pole Figure

An inverse pole figure (IPF) is an image illustrating crystal orientations in a specific direction of the coordinate system based on the TEM sample 500. In the inverse pole figure, the proportion of crystal orientations in each direction of the coordinate system of the TEM sample 500 is shown according to a predetermined index. In general, the proportion of crystal orientations in a specific direction is color-coded according to a color key.

### 2-3. IPF Map

An IPF map is an image in which the crystal orientation in a specific direction of the coordinate system based on the TEM sample 500 is illustrated as a distribution of crystal orientations on the surface of the TEM sample 500. In the IPF map, the crystal orientations at the plurality of measurement points are classified according to a predetermined index indicating the crystal orientation in each direction of the coordinate system of the TEM sample 500. In general, the crystal orientations are color-coded according to a color key.

### 2-4. Crystal Grain

A crystal grain is a crystalline region surrounded by a grain boundary. Since the TEM-ED mapping method obtains information on the crystal orientation, the grain boundary can be defined based on the crystal orientations. In general, when the crystal orientation difference between two adjacent measurement points exceeds 5 degrees, it is defined that a grain boundary exists between them. Therefore, the above definition is also applied to the oxide semiconductor film.

The TEM-ED mapping method is a measurement in a small measurement region. Further, since a thin film sample having a cross section along the film thickness direction is used as a surface of the TEM sample 500, it is difficult to define the crystal grain size of the crystal grains spreading in the plane of the oxide semiconductor layer 140. Therefore, in the present embodiment, the length of the crystal grain obtained based on the cross section of the oxide semiconductor layer 140 in the measurement region is defined as the crystal grain length, instead of the crystal grain size. Specifically, the distance between two crystal grain boundaries obtained in the cross section of the oxide semiconductor layer 140 is defined as the crystal grain length. The crystal grain length defined in this manner may be calculated to be smaller than the crystal grain size. However, the crystal grain size of the crystal grain included in the Poly-OS film is significantly larger than the crystal grain size of the crystal grain included in a conventional oxide semiconductor film. That is, the crystal grain length of the Poly-OS film defined as the above description can be obtained as a value larger than the crystal grain size of the crystal grain included in the conventional oxide semiconductor film. Therefore, it is possible to compare the Poly-OS film with the conventional oxide semiconductor film by using the crystal grain length defined as the above description. In the Poly-OS film, the crystal grain length is greater than or equal to 100 nm, preferably greater than or equal to 300 nm, and more preferably greater than or equal to 500 nm. Although the upper limit of the crystal grain length is not particularly limited, the crystal grain length is less than or equal to 50 μm. The crystal grain length is preferably measured at the central portion of the thickness.

As described above, the crystal grain length of the crystal grain included in the Poly-OS film is large, and one crystal grain may form part of the upper surface and part of the lower surface of the Poly-OS film.

### 2-5. KAM Value

A KAM (Kernel Average Misorientation) value is an average value of the crystal orientation difference between one measurement point in a crystal grain and all measurement points adjacent to the one measurement point. The crystal orientation difference between two adjacent measurement points with a grain boundary interposed therebetween is excluded from the calculation of the KAM value.

The KAM value is a value that represents the change in crystal orientation within one crystal grain. As described above, when the crystal orientation difference between one measurement point and another measurement point adjacent to the one measurement point exceeds 5 degrees, it is considered to be a grain boundary. Therefore, the range of the KAM value calculated based on adjacent measurement points within one crystal grain is greater than or equal to 0 degrees and less than or equal to 5 degrees. A large KAM value means that the local change in crystal orientations within the crystal grain is large, and the crystal grain is highly distorted.

The KAM value is calculated at each of the plurality of measurement points. Therefore, a distribution diagram of the KAM value in the crystal grain can be created. Further, an average value and a standard deviation of the KAM value can be calculated. The average KAM value is a value that represents one of the properties of the crystal grains included in the Poly-OS film. Since the Poly-OS film has a large change in crystal orientation and contains many crystal grains with a large distortion, the average KAM value of the Poly-OS film is larger than that of a conventional oxide semiconductor film having a polycrystalline structure. The average KAM value in the Poly-OS film is greater than or equal to 0.4 degrees, preferably greater than or equal to 0.45 degrees, and more preferably greater than or equal to 0.5 degrees. Similarly, the standard deviation of the KAM value is also a value that represents one of the properties of the crystal grains included in the Poly-OS film. In the Poly-OS film, the standard deviation of the KAM value is greater than or equal to 0.3 degrees, preferably greater than or equal to 0.35 degrees, and more preferably greater than or equal to 0.4 degrees.

Further, the average KAM value in the Poly-OS film increases as the step interval between the measurement points increases. This is due to the large change in crystal orientation within the crystal grain contained in the Poly-OS film, and the tendency for the average KAM value to increase with an increase in the step interval is one of the characteristics of the Poly-OS film.

In addition, the average KAM value described above is the total average KAM value (KAM_{AVE(total)}) calculated using the KAM values of all the measurement points in the measurement region. Unless otherwise specified in the present specification, the average KAM value refers to the total average KAM value (KAM_{AVE(total)}). On the other hand, it is also possible to calculate the average KAM value using some of the measurement points in the measurement region. For example, the thickness of the Poly-OS film can be divided, and the average KAM values of the measurement points included in the divided regions can be calculated. The average KAM values calculated using some of the measurement points is different from the total average KAM value (KAM_{AVE(total)}). The average KAM values calculated by dividing the thickness of the Poly-OS film depends on the distance (depth) of the thickness of the Poly-OS film. Therefore, in the present specification, the average value is sometimes referred to as the depth average KAM value (KAM_{AVE(depth)}) to be distinguished from the total average KAM value (KAM_{AVE(total)}).

As described above, since the crystal grain length of the Poly-OS film is large, the Poly-OS film may be formed of one crystal grain from the upper surface to the lower surface. In the Poly-OS film, the crystal orientation also changes significantly in the thickness direction of the Poly-OS film. Specifically, the depth average value (KAM_{AVE(depth)}) of the KAM value is different between the upper end portion and the lower end portion (which are near the interface, for example, within 3 nm from the interface) and the central portion (which is near a center, for example, within 5 nm located equidistant from the upper end portion and the lower end portion) of the Poly-OS film. The depth average value (KAM_{AVE(depth)}) of the KAM value at each of the upper end portion and the lower end portion of the Poly-OS film is greater than or equal to 0.3 degrees and less than 5.0 degrees, preferably greater than or equal to 0.4 degrees and less than 5.0 degrees, and further preferably greater than or equal to 0.5 degrees and less than 5.0 degrees. On the other hand, the depth average KAM value (KAM_{AVE(depth)}) at the central portion of the Poly-OS film is less than 0.5 degrees. The difference in the depth average KAM value (KAM_{AVE(depth)}) between the upper end portion or the lower end portion and the central portion of the Poly-OS film is greater than or equal to 0.05 degrees, preferably greater than or equal to 0.1 degrees, and further preferably greater than or equal to 0.15 degrees.

The upper surface and the lower surface of the Poly-OS film may have unevenness. In this case, the number of measurement points at the upper end portion and the lower end portion is reduced, and the error in the depth average KAM values (KAM_{AVE(depth)}) at the upper end portion and the lower end portion is likely to be large. Therefore, the depth average KAM values (KAM_{AVE(depth)}) at the upper end portion and the lower end portion may be calculated by using a region in which the number of measurement points included in the divided region is greater than or equal to 90% of the number of measurement points in the central portion (or a region in which the number of measurement points is greater than or equal to 90% of the maximum number of measurement points) as an effective region. In an effective Poly-OS film including the effective region, the depth average KAM values (KAM_{AVE(depth)}) at the upper end portion and the lower end portion can be calculated without being affected by the unevenness formed on the upper surface and the lower surface.

As described above, the TEM-ED mapping method can obtain information about the crystal orientation in the crystal grain included in the Poly-OS film. For example, when the Poly-OS film has a bixbyite structure, the TEM-ED mapping method can observe that the Poly-OS film includes a crystal grain with a crystal orientation of <001>, <101>, or <111>.

Here, the crystal orientation <001> represents and its equivalents and [010]. The crystal orientation <101> represents and its equivalents and [011]. The crystal orientation <111> represents [111].Further, in each orientation, “1” may be “−1” and is considered to be an axis equivalent to each orientation.

Further, crystal orientations include <hk0> (h≠k, h and k are natural numbers), <hhl> (h≠l, h and l are natural numbers), and <hkl> (h≠k≠l, h, k, and I are natural numbers) other than <001>, <101>, and <111>.

The crystal grains in the Poly-OS film have a property whereby the crystal orientation changes significantly within the crystal grain. When the characteristics of the Poly-OS film are quantified by a TEM-ED method, the average KAM value of the Poly-OS film is greater than or equal to 0.4 degrees. In the case of the conventional oxide semiconductor film, when the change in the crystal orientation within the crystal grain is large, crystal dislocation is likely to occur, and the crystal grain size of the crystal grain is small. However, in the Poly-OS film, although the change in the crystal orientation within the crystal grain is large, the crystal grain length (or crystal grain size) of the crystal grain is large as described above. Such a characteristic of the Poly-OS film is completely different from that of the conventional oxide semiconductor film. As a result of trial and error, the inventors have found the Poly-OS film having a novel crystal structure. The Poly-OS film is less likely to receive the influence of crystal grain boundaries because it includes large crystal grains. Therefore, in the thin film transistor 10 including the Poly-OS film as the channel, the channel is less likely to receive the influence of grain boundaries, grain boundary scattering is suppressed, and field effect mobility is improved.

In addition, the crystal orientation of the crystal grain in the Poly-OS film is described in detail later along with examples.

As described above, the oxide semiconductor film according to an embodiment of the present invention, i.e., the Poly-OS film, has a novel crystal structure. Specifically, the Poly-OS film includes crystal grains with a large change in crystal orientation and with a large crystal grain length (or crystal grain size), unlike a conventional oxide semiconductor film.

### Second Embodiment

FIG. 2 is a schematic cross-sectional view showing a configuration of the thin film transistor 10 according to an embodiment of the present invention. For example, the thin film transistor 10 may be used in an integrated circuit (IC) such as a micro-processing unit (MPU) or a memory circuit in addition to a transistor used in a display device.

As shown in FIG. 2, the thin film transistor 10 includes a silicon substrate 100, a gate insulating layer 120, an oxide semiconductor layer 140, a protective insulating layer 160, a source electrode 201, and a drain electrode 203. The gate insulating layer 120 is provided on the silicon substrate 100. The oxide semiconductor layer 140 is provided on the gate insulating layer 120. That is, the thin film transistor 10 includes a laminated structure including the gate insulating layer 120 and the oxide semiconductor layer 140 in contact with the gate insulating layer 120. The protective insulating layer 160 is provided on the gate insulating layer 120 so as to cover an upper surface and edge surfaces of the oxide semiconductor layer 140. The protective insulating layer 160 is provided with opening portions 161 and 163 through which a part of the upper surface of the oxide semiconductor layer 140 is exposed. The source electrode 201 is provided on the protective insulating layer 160 and inside the opening portion 161, and is in contact with the oxide semiconductor layer 140. Similarly, the drain electrode 203 is provided on the protective insulating layer 160 and inside the opening portion 163, and is in contact with the oxide semiconductor layer 140. In the following description, when the source electrode 201 and the drain electrode 203 are not particularly distinguished from each other, they may be collectively referred to as a source-drain electrodes 200.

The silicon substrate 100 can function for a gate electrode. Therefore, the oxide semiconductor layer 140 includes a channel region CH formed between the source electrode 201 and the drain electrode 203. The silicon substrate 100 may have conductivity. That is, the silicon substrate 100 may be a silicon substrate having n-type conductivity or p-type conductivity.

The gate insulating layer 120 is formed by thermally oxidizing the silicon substrate 100. That is, the gate insulating layer 120 is a so-called silicon thermal oxide film. Although the thickness of the gate insulating layer 120 is, for example, 100 nm, the thickness is not limited thereto.

The oxide semiconductor layer 140 is deposited on the silicon thermal oxide film by a sputtering method. For example, the thickness of the oxide semiconductor layer 140 is greater than or equal to 10 nm and less than or equal to 100 nm, preferably greater than or equal to 15 nm and less than or equal to 70 nm, and more preferably greater than or equal to 15 nm and less than or equal to 50 nm. The oxide semiconductor film is amorphous immediately after the deposition. In the Poly-OS technology, the oxide semiconductor film after the deposition and before the heat treatment is preferably amorphous so that the oxide semiconductor layer 140 has a uniform polycrystalline structure in the substrate plane. Therefore, the deposition conditions of the oxide semiconductor film are preferably conditions under which the oxide semiconductor film immediately after the deposition is not crystallized as much as possible. Further, the oxide semiconductor film 145 is deposited under the condition of a low oxygen partial pressure. The oxygen partial pressure is greater than or equal to 1% and less than or equal to 20%, preferably greater than or equal to 1% and less than or equal to 15%, and more preferably greater than or equal to 1% and less than 10%.

A heat treatment (hereinafter, referred to as “OS annealing”) is performed on the oxide semiconductor film which is patterned using a photography method in order to form the oxide semiconductor layer 140 having a polycrystalline structure (i.e., the oxide semiconductor layer 140 including the Poly-OS film). In the OS annealing process, the oxide semiconductor film is held at a predetermined reaching temperature for a predetermined time. The predetermined reaching temperature is higher than or equal to 250° C. and lower than or equal to 500° C., and preferably higher than or equal to 300° C. and lower than or equal to 400° C. Further, the predetermined time (holding time) at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure by the OS annealing process. In addition, the OS annealing process may be performed before or after the protective insulating layer 160 is formed. Further, the number of times the OS annealing process is performed is not limited to one, and may be performed multiple times before and after the protective insulating layer 160 is formed.

The protective insulating layer 160 can prevent impurities from diffusing into the oxide semiconductor layer 140. Specifically, the protective insulating layer 160 can prevent the diffusion of impurities (e.g., water) entering from the outside. Although the thickness of the protective insulating layer 160 is greater than or equal to 50 nm and less than or equal to 500 nm, the thickness is not limited thereto. For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) and the like are used for the productive insulating layer 160. Here, silicon oxynitride (SiOₓN_{y}) and aluminum oxynitride (AlOₓN_{y}) are a silicon compound and an aluminum compound, respectively, that contain a smaller proportion (x>y) of nitrogen (N) than oxygen (O). Silicon nitride oxide (SiNₓO_{y}) and aluminum nitride oxide (AlNₓO_{y}) are a silicon compound and an aluminum compound, respectively, that contain a smaller proportion (x>y) of oxygen than nitrogen. Further, the protective insulating layer 160 may have a single layer structure or a laminated structure.

The protective insulating layer 160 may have a planarization function or a function of releasing oxygen by performing a heat treatment. For example, when the protective insulating layer 160 has a function of releasing oxygen by performing a heat treatment, oxygen is released from the protective insulating layer 160 by the heat treatment performed in the manufacturing process of the thin film transistor 10, and the released oxygen can be supplied to the oxide semiconductor layer 140. When the OS annealing process is performed after the formation of the protective insulating layer 160, silicon oxide (SiOₓ) or silicon oxynitride (SiOₓN_{y}) is preferably used for the protective insulating layer 160 if the protective insulating layer 160 has a single-layer structure and silicon oxide (SiOₓ) or silicon oxynitride (SiOₓN_{y}) is preferably used for a layer in contact with the oxide semiconductor layer 140 included in the protective insulating layer 160 if the protective insulating layer 160 has a laminated structure.

The source electrode 201 and the drain electrode 203 are conductive. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or alloys or compounds thereof can be used for each of the source electrode 201 and the drain electrode 203. Each of the source electrode 201 and the drain electrode 203 may have a single layer structure or a laminated structure. The source electrode 201 and the drain electrode 203 are formed in the opening portions 161 and 163 of the protective insulating layer 160 and are electrically connected to the oxide semiconductor layer 140.

Although the configuration of the thin film transistor 10 is described above, the thin film transistor 10 described above is a so-called bottom-gate transistor. The thin film transistor 10 can be modified in various ways. The thin film transistor 10 may be a so-called top-gate transistor or dual-gate transistor.

In the thin film transistor 10 according to the present embodiment, the oxide semiconductor layer 140 includes the Poly-OS film having a novel crystal structure. The Poly-OS film includes the crystal grain with a large change in crystal orientation and a large crystal grain length (or crystal grain size). Therefore, in the thin film transistor 10 including the Poly-OS film as a channel, the channel as a whole is less likely to receive the influence of crystal grain boundaries. Further, it is considered that the crystal orientation in the crystal grains changes so as to improve the lattice matching at the crystal grain boundaries, and as a result, crystal grain boundaries with fewer defects are generated. For these reasons, in the thin film transistor 10 including the Poly-OS film as a channel, grain boundary scattering is suppressed and field effect mobility is improved.

### Third Embodiment

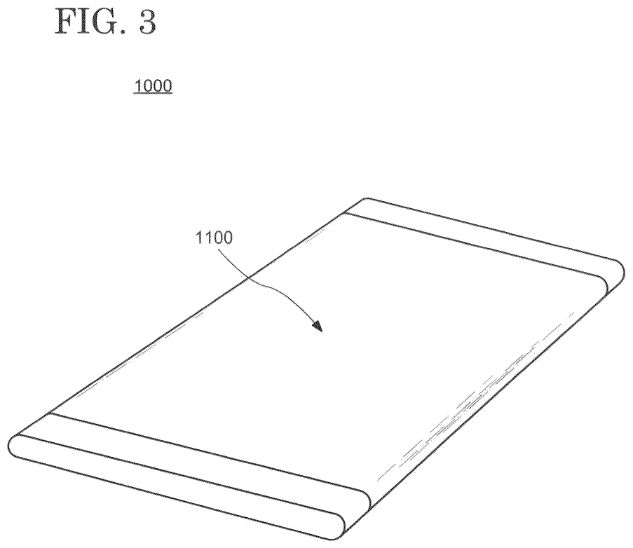

An electronic device according to an embodiment of the present embodiment is described with reference to FIG. 3.

FIG. 3 is a schematic diagram showing an electronic device 1000 according to an embodiment of the present embodiment. Specifically, FIG. 3 shows a smartphone, which is an example of the electronic device 1000. The electronic device 1000 includes a display device 1100 with curved sides. The display device 1100 includes a plurality of pixels for displaying an image. The plurality of pixels is controlled by a pixel circuit, a drive circuit, and the like. The pixel circuit and the drive circuit include the thin film transistor 10 described in the First Embodiment. Since the thin film transistor 10 has high field effect mobility, the responsiveness of the pixel circuit and the drive circuit can be improved, and as a result, the performance of the electronic device 1000 can be improved.

In addition, the electronic device 1000 according to the present embodiment is not limited to a smartphone. For example, the electronic device 1000 also includes an electronic device having a display device, such as a watch, a tablet, a notebook computer, a car navigation system, or a television. Further, the thin film transistor 10 described in the Second Embodiment can be applied to any electronic device, regardless of whether or not the electronic device has a display device.

### EXAMPLES

An oxide semiconductor layer (specifically, a Poly-OS film) is described in further detail based on the manufactured thin film transistor.

### 1. Fabrication of Thin Film Transistor

A thin film transistor described in the Second Embodiment was fabricated. In the sputtering process for depositing the oxide semiconductor layer, a sputtering target in which indium (In) and gallium (Ga) as the first metal element (M1) are contained and indium making up 70% in atomic ratio to all metal elements contained in the sintered body was used to deposit an oxide semiconductor layer with a thickness of 50 nm. The oxygen partial pressure during film deposition was 10%. In the OS annealing process, the reaching temperature was controlled between 300° C. and 400° C. in an air atmosphere, and the reaching temperature was held for 60 minutes. The chemical composition of the oxide semiconductor layer after the OS annealing process was the same as that of the sputtering target. In addition, the first metal element (M1) contained in the sintered body of the example is not limited to gallium (Ga). Aluminum (AI), yttrium (Y), scandium (Sc), and lanthanoid elements also shows similar effects. The OS annealing process was performed twice, before and after the formation of the protective insulating layer.

2. Crystal Orientation Analysis using TEM-ED Mapping Method

A TEM sample (hereinafter referred to as an “example sample”) was prepared by sampling a cross section of a region including an oxide semiconductor layer of a thin film transistor by FIB processing, and a crystal orientation analysis of a Poly-OS film included in the oxide semiconductor layer was performed by TEM-ED mapping. The measurement conditions for the TEM-ED mapping are shown in Table 1. An ASTAR manufactured by NanoMegas Corporation was used for the analysis of the crystal orientation. A powder diffraction file (PDF) of 04-024-4517 of IC DD (International Centre for Diffraction Date) was used for orientation of the crystal structure.

TABLE 1

| Device | JEM-ARM200F manufactured by JEOL Ltd. |
|---|---|
| Acceleration | 200 kV |
| Voltage | |
| Measurement | 60 nm × 1200 nm |
| Region | |
| Step Interval | 1 nm |

### 2-1. Inverse Pole Figure

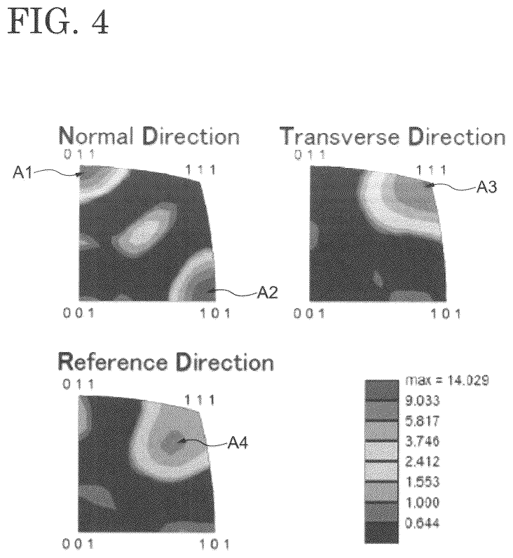

FIG. 4 is an inverse pole figure of the oxide semiconductor layer (Poly-OS film) of the example sample. FIG. 4 shows inverse pole figures for ND, TD, and RD. In the inverse pole figures for ND, TD, and RD, the proportion of the crystal orientation increases according to the value of the index shown in FIG. 4 (for example, the index may be a color key, and the proportion of the crystal orientation increases as the color changes from blue to red (the wavelength of visible light increases)). There are regions (regions A1, A2, A3, and A4) having large values in any of ND, TD, and RD, and it was found that there are specific crystal orientations with a large proportion. For example, in RD corresponding to the thickness direction of the oxide semiconductor layer, the proportion of the crystal orientation <111> is larger than that of the crystal orientation <001> and the crystal orientation <101>.

Although the main crystal orientation in each of ND, TD, and RD is not particularly limited, it is preferable that the proportion of one of the crystal orientation <001>, the crystal orientation <101>, and the crystal orientation <111> is large in any one of the directions of ND, TD, and RD.

s2-2. IPF Map

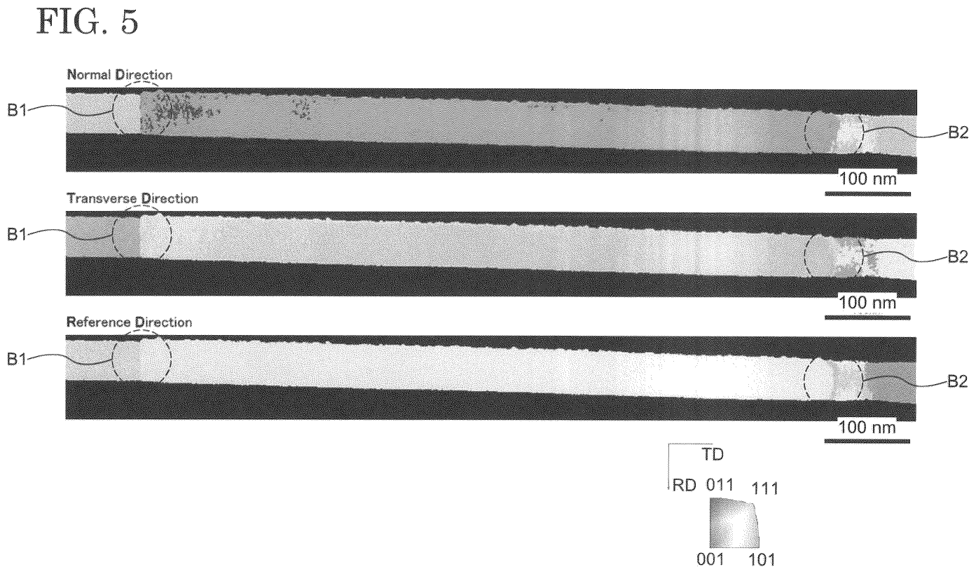

FIG. 5 is an IPF map of the oxide semiconductor layer (Poly-OS film) of the example sample. FIG. 5 shows IPF maps for ND, TD, and RD. In FIG. 5, the crystal orientation <001>, the crystal orientation <101>, the crystal orientation <111>, and the crystal orientation <011> are classified according to the indices in the figure.

In regions B1 and B2 shown in FIG. 5, the crystal orientation changes significantly and discontinuously. The discontinuous change in the crystal orientation corresponds to a grain boundary, and it is confirmed that a grain boundary forms from the upper surface to the lower surface (or from the lower surface to the upper surface) of the oxide semiconductor layer in the regions B1 and B2. The grain length of one crystal grain between the grain boundaries defined by the region B1 and B2 is 813 nm. Further, one crystal grain formed a part of the upper surface and a part of the lower surface of the oxide semiconductor layer. That is, the grain length is greater than or equal to 10 times the thickness of the oxide semiconductor layer.

The crystal orientations within the grains in the IPF maps corresponded to the proportions of crystal orientations in the inverse pole figures described above. For example, the main crystal orientation of the grain in the RD is the crystal orientation <111>.

In addition, although not shown in the figures, crystal grain boundaries can also be confirmed in the TEM image in the regions B1 and B2.

### 2-3. KAM Value

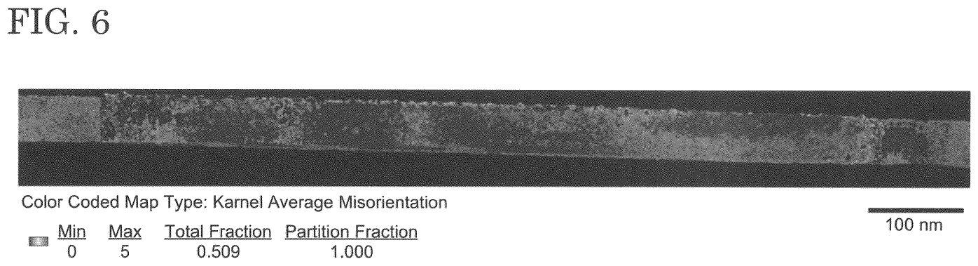

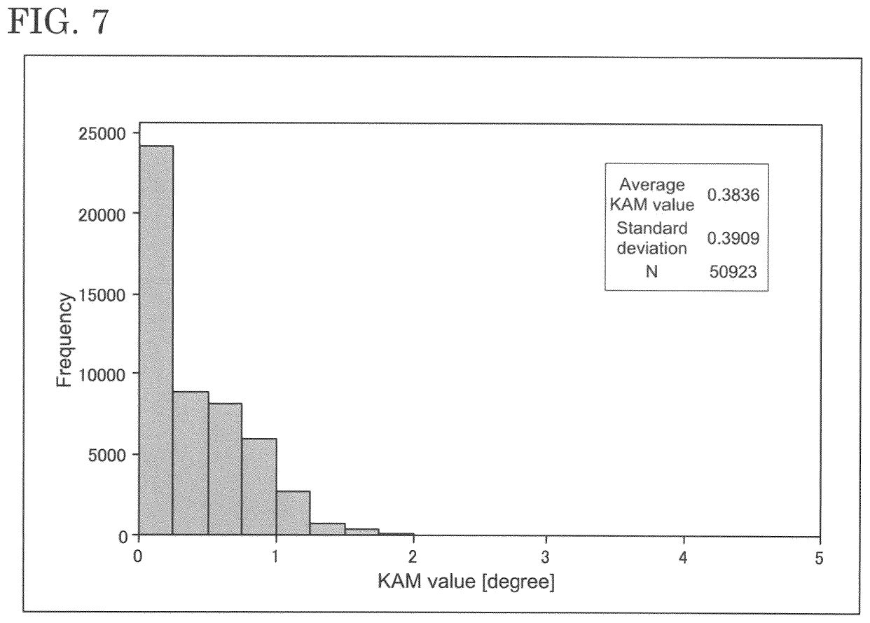

FIG. 6 is a KAM map of the oxide semiconductor layer (Poly-OS film) of the example sample. Specifically, in FIG. 6, the KAM values of the measurement points in the measurement region are classified according to the values of the indices shown in the figure (for example, the indices may be a color key, and the KAM value increases from 0 degrees to 5 degrees as the color changes from blue to red (the wavelength of visible light increases)). In addition, when the crystal orientation difference between two adjacent measurement points exceeds 5 degrees, it is regarded as a grain boundary, and therefore the upper limit of the KAM value is 5 degrees. FIG. 7 is a graph showing the distribution of the KAM values of the oxide semiconductor layer (Poly-OS film) of the example sample.

As shown in FIG. 6, the oxide semiconductor layer has many regions having a KAM value near 0 degrees (corresponding to the region shown in blue in the color key, hereinafter, for convenience of explanation, it is referred to as a “blue region”), while scattered regions having a KAM value other than near 0 degrees (corresponding to the region shown in green in the color key, hereinafter, for convenience of explanation, it is referred to as a “green region”). As an overall tendency, the blue region spread in the central portion of the oxide semiconductor layer, and the green region spread near the surface (near the upper end portion and the lower end portion) of the oxide semiconductor layer. As can be seen from FIG. 7, it can be confirmed that there are many measurement points having a KAM value other than 0 degrees while there are many measurement points having a KAM value near 0 degrees. The total average KAM value (KAM_{AVE(total)}) calculated using the KAM values of all the measurement points is 0.384 degrees. Further, the standard deviation (σ) of the KAM value is 0.391 degrees. In addition, since the KAM values at two adjacent measurement points change gradually, the total average KAM values (KAM_{AVE(total)}) increases as the step interval increases.

Although the TEM-ED mapping method is a measurement in a microscopic region, the total average value and standard deviation of the KAM value are large even in such a microscopic region in the case of the Poly-OS film. This means that there is a large change in crystal orientation within the crystal grain of the Poly-OS film. Although the crystal grain in the Poly-OS film has a large crystal grain length (or crystal grain size), there is a large local change in crystal orientation. This is one of the characteristics of the Poly-OS film that is not observed in the conventional oxide semiconductor film having a polycrystalline structure.

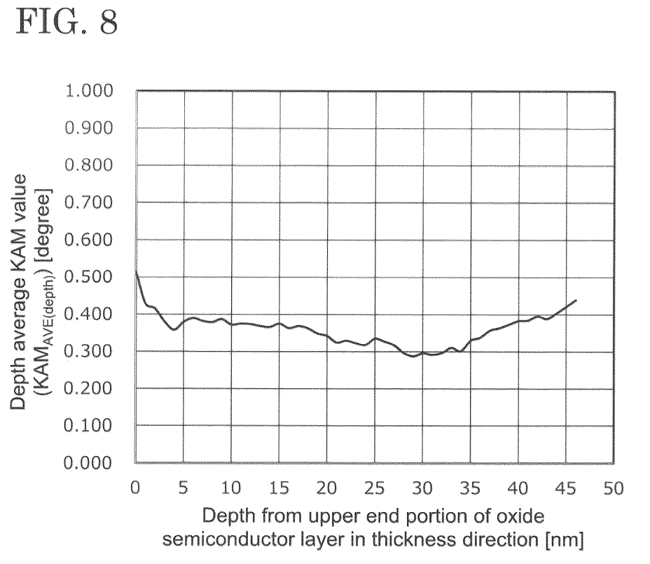

FIG. 8 is a graph showing a depth average KAM value in the oxide semiconductor layer (Poly-OS film) of the example sample. As described above, a difference is observed in the distribution of the KAM value between the central portion of the oxide semiconductor layer and the vicinity of the surface (the vicinity of the upper end portion and the lower end portion). Therefore, the KAM values of the measurement points are collected for each distance from the interface between the protective insulating layer and the oxide semiconductor layer (the depth of the oxide semiconductor layer), and the depth average KAM value (KAM_{AVE(depth)}) is calculated, which is the average value of the collected measurement points. The depth average KAM value (KAM_{AVE(depth)}) is the average KAM value of some measurement points divided according to the depth of the oxide semiconductor layer. In addition, a region in which the number of measurement points included in the divided region is greater than or equal to 90% of the number of measurement points in the central portion is set as a valid region in order to exclude the influence of the unevenness of the surface of the oxide semiconductor layer, and the depth average KAM value (KAM_{AVE(depth)}) of the oxide semiconductor layer is calculated. In the graph shown in FIG. 8, the depth average KAM value (KAM_{AVE(depth)}) is plotted against the depth in the thickness direction of the oxide semiconductor layer.

As shown in FIG. 8, the depth average KAM value (KAM_{AVE(depth)}) is larger at the upper end portion near the interface between the oxide semiconductor layer and the protective insulating layer and at the lower end portion near the interface between the oxide semiconductor layer and the gate insulating layer than at the central portion of the oxide semiconductor layer. The average depth KAM values (KAM_{AVE(depth)}) at the central portion (depth 25 nm), upper end portion (depth 0 nm), and lower end portion (depth 46 nm) are 0.335 degrees, 0.515 degrees, and 0.439 degrees, respectively. The difference in the average depth KAM values (KAM_{AVE(depth)}) between the upper end portion and the central portion is greater than or equal to 0.15 degrees. Further, the difference in the average depth KAM values (KAM_{AVE(depth)}) between the lower end portion and the central portion is greater than or equal to 0.1 degrees. That is, in the average depth KAM values (KAM_{AVE(depth)}), both the difference between the upper end portion and the central portion and the difference between the lower end portion and the central portion are greater than or equal to 0.05 degrees.

The above results indicate that crystal orientation near the interface of the oxide semiconductor layer changes. In the Poly-OS film, the change in local crystal orientation is large even in the thickness direction. In the conventional oxide semiconductor film having a polycrystalline structure, since the crystal grain length (or crystal grain size) is small so that strain in the crystal grain is relaxed, it is difficult to form the oxide semiconductor film from the upper surface to the lower surface with one crystal grain. On the other hand, in the Poly-OS film, it is possible to form the oxide semiconductor film from the upper surface to the lower surface with one crystal grain that has a large change in crystal orientation. This is one of the characteristics of the Poly-OS film that is not observed in the conventional oxide semiconductor film having a polycrystalline structure.

### 3. Electrical Characteristics

The electrical characteristics of the fabricated thin film transistor were measured. The field effect mobility calculated from the electrical characteristics was 19.9 cm²/Vs. It is confirmed that when the Poly-OS film is used as a channel of a thin film transistor, a field effect mobility (field effect mobility in a saturated region) greater than 15 cm²/Vs can be obtained. In addition, the mobility in the linear region exceeded 30 cm²/Vs.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each of the embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. An oxide semiconductor film over a substrate, comprising a plurality of crystal grains, the oxide semiconductor film comprising:
indium; and
a first metal element selected from the group consisting of aluminum (Al), gallium (Ga), yttrium (Y), scandium (Sc), and lanthanoid elements,
wherein when a crystal orientation at each of a plurality of measurement points of the oxide semiconductor film is obtained based on an electron diffraction pattern obtained by transmitting an electron beam irradiated from a direction intersecting a thickness direction of the oxide semiconductor film, an average value of KAM values calculated at the plurality of measurement points is greater than or equal to 0.3 degrees.

2. The oxide semiconductor film according to claim 1,
wherein the electron diffraction pattern at each of the plurality of measurement points is observed at a predetermined step interval, and
wherein the predetermined step interval is greater than or equal to 1 nm.

3. The oxide semiconductor film according to claim 2, wherein the predetermined step interval is less than or equal to ⅕ of a thickness of the oxide semiconductor film.

4. The oxide semiconductor film according to claim 2, wherein the average value increases as the predetermined step interval increases.

5. The oxide semiconductor film according to claim 1, wherein at least one of two crystal grains adjacent to each other across a grain boundary forms a part of an upper surface and a part of a lower surface of the oxide semiconductor film.

6. The oxide semiconductor film according to claim 5, wherein a gap between two adjacent measurement points is defined as a grain boundary when the crystal orientation difference between the two adjacent measurement points exceeds 5 degrees.

7. The oxide semiconductor film according to claim 1, wherein a depth average value of KAM values at each of an upper end portion and a lower end portion of the oxide semiconductor film is greater than or equal to 0.4 degrees.

8. The oxide semiconductor film according to claim 1, wherein a difference between a depth average of KAM values at an upper end portion or a lower end portion of the oxide semiconductor film and a depth average of KAM values at a center portion of the oxide semiconductor film is greater than or equal to 0.05 degrees.

9. The oxide semiconductor film according to claim 1, wherein at least one of the plurality of crystal grains has a crystal grain length greater than or equal to 100 nm in the direction intersecting the thickness direction of the oxide semiconductor film.

10. The oxide semiconductor film according to claim 1,
wherein the oxide semiconductor film further comprises a second metal element (M2) selected from the group consisting of aluminum, yttrium, scandium, and lanthanoid elements,
wherein the first metal element is gallium, and
wherein atomic ratios of the indium, the gallium, and the second metal element satisfy formulas (1), (2), and (3).
$$0.7 \leq \frac{[ ln ]}{[ ln ] + [ Ga ] + [ M 2 ]} \leq 0.98 \qquad ( 1 )$$
$$0.01 \leq \frac{[ Ga ]}{[ ln ] + [ Ga ] + [ M 2 ]} < 0.2 \qquad ( 2 )$$
$$0.01 \leq \frac{[ M 2 ]}{[ ln ] + [ Ga ] + [ M 2 ]} < 0.1 \qquad ( 3 )$$

11. The oxide semiconductor film according to claim 1, wherein a crystal structure of the oxide semiconductor film is a bixbyite structure.

12. A laminated structure, comprising:
the oxide semiconductor film according to claim 1; and
a silicon oxide film under and in contact with the oxide semiconductor film.

13. A thin film transistor comprising the oxide semiconductor film according to claim 1 as a channel.

14. A thin film transistor comprising the laminated structure according to claim 12.

15. An electronic device comprising the thin film transistor according to claim 13.

16. An electronic device comprising the thin film transistor according to claim 14.
